(19) United States
(12) Patent Application Publication
(10) Pub. No.: US 2025/0113608 A1
(43) Pub. Date: Apr. 3, 2025

(54) THIN-FILM TRANSISTOR AND METHOD FOR MANUFACTURING SAME, AND DISPLAY PANEL

(71) Applicants: Nanjing BOE Display Technology Co., Ltd., Nanjing, Jiangsu (CN); BOE Technology Group Co., Ltd., Beijing (CN)

(72) Inventors: Yanlong LI, Beijing (CN); Huirong SHANG, Beijing (CN); Kun CAO, Beijing (CN); Hongtao HUANG, Beijing (CN); Qin ZHANG, Beijing (CN)

(73) Assignees: Nanjing BOE Display Technology Co., Ltd., Nanjing, Jiangsu (CN); BOE Technology Group Co., Ltd., Beijing (CN)

(21) Appl. No.: 18/289,227

(22) PCT Filed: Sep. 26, 2022
(86) PCT No.: PCT/CN2022/121471

§ 371 Date: Nov. 2, 2023

(51) Int. Cl. H10D 86/40; G02F 1/1368; H10D 30/01; H10D 30/67; H10D 86/01

(52) U.S. Cl. CPC H10D 86/423; G02F 1/1368; H10D 30/031; H10D 30/6704; H10D 30/6755; H10D 86/0221; H10D 86/441

(57) ABSTRACT

Provided is a thin-film transistor. The thin-film transistor includes: a gate, a first insulative layer, a semiconductor layer, a source and drain layer, a semiconductor modification layer, and a second insulative layer that are disposed on a base substrate and sequentially laminated in a direction away from the base substrate; wherein the source and drain layer includes a source and a drain that are spaced apart and both connected to the semiconductor layer, a portion of the semiconductor layer is exposed from a gap between the source and the drain, and the semiconductor modification layer at least covers the portion of the semiconductor layer exposed from the gap; and a concentration of hydrogen in the semiconductor layer is greater than a concentration threshold, and a temperature of a reaction chamber in manufacturing the thin-film transistor is less than a temperature threshold.

### CROSS-REFERENCE TO RELATED APPLICATION

This application is a U.S. national stage of international application No. PCT/CN2022/121471, filed on Sep. 26, 2022, the disclosure of which is incorporated herein by reference in its entirety.

### TECHNICAL FIELD

The present disclosure relates to the field of display technologies, and in particular, relates to a thin-film transistor and a method for manufacturing the same, and a display panel.

### BACKGROUND

Thin-film transistors (TFT), as a switch control element of a pixel circuit or an integrated element of a periphery driving circuit, are core elements of a display device. In addition, the TFT greatly affects a resolution, a response speed, and a color reality of the display device.

### SUMMARY

Embodiments of the present disclosure provide an array substrate and a method for manufacturing the same, and a liquid crystal panel. The technical solutions are as follows.

In some embodiments of the present disclosure, a thin-film transistor is provided. The thin-film transistor includes: a gate, a first insulative layer, a semiconductor layer, a source and drain layer, a semiconductor modification layer, and a second insulative layer that are disposed on a base substrate and sequentially laminated in a direction away from the base substrate; wherein
the source and drain layer includes a source and a drain that are spaced apart and both connected to the semiconductor layer, a portion of the semiconductor layer is exposed from a gap between the source and the drain, and the semiconductor modification layer at least covers the portion of the semiconductor layer exposed from the gap; and
a number of hydrogen atoms in per cubic centimeter of the semiconductor layer is greater than 16×10\hat{ }20 and less than 26×10\hat{ }20.

In some embodiments, in a face, proximal to the base substrate, of the semiconductor modification layer, a distance between a portion most proximal to the base substrate and a portion most distal from the base substrate in a direction perpendicular to a bearing face of the base substrate is greater than or equal to 0 nm and less than or equal to 15 nm.

In some embodiments, a ratio of a thickness of the semiconductor modification layer to a thickness of the second insulative layer ranges from 1/25 to ⅓.

In some embodiments, the thickness of the semiconductor modification layer ranges from 20 nm to 200 nm, and the thickness of the second insulative layer ranges from 100 nm to 350 nm.

In some embodiments, a material of the semiconductor layer includes an oxide;
a material of the semiconductor modification layer includes a silicon oxide; and
a material of the second insulative layer includes a silicon oxide, or a silicon oxide and a silicon nitride.

In some embodiments of the present disclosure, a method for manufacturing a thin-film transistor is provided. The method includes:
sequentially forming a gate, a first insulative layer, a semiconductor layer, and a source and drain layer on a base substrate in a reaction chamber, wherein the source and drain layer includes a source and a drain that are spaced apart and both connected to the semiconductor layer, and a portion of the semiconductor layer is exposed from a gap between the source and the drain;
controlling a temperature of the reaction chamber to be a first temperature, and forming a semiconductor modification layer on a side, distal from the base substrate, of the source and drain layer, wherein the semiconductor modification layer at least covers the portion of the semiconductor layer exposed from the gap; and
controlling the temperature of the reaction chamber to be a second temperature, and forming a second insulative layer on a side, distal from the base substrate, of the semiconductor modification layer, wherein the second temperature is greater than the first temperature,
a concentration of hydrogen in the semiconductor layer is greater than a concentration threshold, and the first temperature, the second temperature, and a temperature of the reaction chamber in forming the gate, the first insulative layer, the semiconductor layer, and the source and drain layer are all less than a temperature threshold.

In some embodiments, forming the semiconductor modification layer on the side, distal from the base substrate, of the source and drain layer includes:
introducing silicon tetrahydride to the reaction chamber, and forming the semiconductor modification layer on the side, distal from the base substrate, of the source and drain layer by a chemical vapor deposition process;
forming the second insulative layer on the side, distal from the base substrate, of the semiconductor modification layer includes:
introducing silicon tetrahydride and ammonia to the reaction chamber, and forming the second insulative layer on the side, distal from the base substrate, of the semiconductor modification layer by the chemical vapor deposition process;
wherein the hydrogen in the semiconductor layer is from hydrogen in the silicon tetrahydride introduced to the reaction chamber in forming the semiconductor modification layer and hydrogen in the silicon tetrahydride and the ammonia introduced to the reaction chamber in forming the second insulative layer.

In some embodiments, in the hydrogen in the semiconductor layer, a content of hydrogen in silicon tetrahydride introduced to the reaction chamber in forming the semiconductor modification layer is greater than a content of hydrogen in silicon tetrahydride and ammonia introduced to the reaction chamber in forming the second insulative layer.

In some embodiments, upon formation of the source and drain layer and prior to formation of the semiconductor modification layer, the method further includes:
controlling the temperature of the reaction chamber to be a third temperature, and performing plasma treatment on the semiconductor layer, wherein the third temperature is less than the temperature threshold.

In some embodiments, a number of hydrogen atoms in per cubic centimeter of the semiconductor layer is greater than 16×10\hat{ }20 and less than 26×10\hat{ }20.

In some embodiments, the temperature threshold is less than or equal to 250° C., the first temperature ranges from 130° C. to 200° C., and the second temperature ranges from 220° C. to 340° C.

In some embodiments of the present disclosure, a display panel is provided. The display panel includes: a base substrate and a plurality of thin-film transistors on the base substrate; wherein each of the plurality of thin-film transistors includes: a gate, a first insulative layer, a semiconductor layer, a source and drain layer, a semiconductor modification layer and a second insulative layer that are disposed on the base substrate and sequentially laminated in a direction away from the base substrate; wherein
the source and drain layer includes a source and a drain that are spaced apart and both connected to the semiconductor layer, a portion of the semiconductor layer is exposed from a gap between the source and the drain, and the semiconductor modification layer at least covers the portion of the semiconductor layer exposed from the gap; and
a number of hydrogen atoms in per cubic centimeter of the semiconductor layer is greater than 16×10\hat{ }20 and less than 26×10\hat{ }20.

In some embodiments, the base substrate includes a display region and a periphery region surrounding the display region, the plurality of thin-film transistors are at least disposed in the display region, and the display panel further includes: a signal wiring in the periphery region, wherein

the signal wiring includes a first wiring segment and a second wiring segment that are disposed in different layers, the display panel further includes a target insulative layer between the first wiring segment and the second wiring segment, and the first wiring segment is electrically connected to the second wiring segment by a via in the target insulative layer.

In some embodiments, the first wiring segment and the gate are made of the same material by one patterning process, the second wiring segment and the source and drain layer are made of the same material by one patterning process, and the target insulative layer is the first insulative layer.

### BRIEF DESCRIPTION OF DRAWINGS

For clearer description of the technical solutions in the embodiments of the present disclosure, the following briefly introduces the accompanying drawings required for describing the embodiments. Apparently, the accompanying drawings in the following description show merely some embodiments of the present disclosure, and a person of ordinary skill in the art may still derive other drawings from these accompanying drawings without creative efforts.

FIG. 1 is a scanning electron microscopy of a section view of a thin-film transistor in some practices;

FIG. 2 is a schematic structural diagram of a thin-film transistor according to some embodiments of the present disclosure;

FIG. 3 is a scanning electron microscopy of a section view of a thin-film transistor according to some embodiments of the present disclosure;

FIG. 4 is a schematic diagram of a relationship of a current and a voltage according to some embodiments of the present disclosure;

FIG. 5 is a schematic diagram of a relationship of a total resistance of a thin-film transistor and a length of a channel of a thin-film transistor according to some embodiments of the present disclosure;

FIG. 6 is a schematic diagram of a relationship of a contact resistance of a thin-film transistor and a length of a channel of a thin-film transistor in some practices;

FIG. 7 is a schematic diagram of a relationship of a contact resistance of a thin-film transistor and a length of a channel of a thin-film transistor according to some embodiments of the present disclosure;

FIG. 8 is a schematic diagram of a relationship of a content of hydrogen and a depth of a film layer according to some embodiments of the present disclosure;

FIG. 9 is a schematic diagram of another relationship of a current and a voltage according to some embodiments of the present disclosure;

FIG. 10 is a flowchart of a method for manufacturing a thin-film transistor according to some embodiments of the present disclosure;

FIG. 11 is a schematic structural diagram of a display panel according to some embodiments of the present disclosure;

FIG. 12 is a flowchart of a method for manufacturing a display panel according to some embodiments of the present disclosure;

FIG. 13 is a schematic diagram of forming a gate and a first wiring segment according to some embodiments of the present disclosure;

FIG. 14 is a schematic diagram of forming a first insulative thin film according to some embodiments of the present disclosure;

FIG. 15 is a schematic diagram of forming a semiconductor layer according to some embodiments of the present disclosure;

FIG. 16 is a schematic diagram of forming a first insulative layer according to some embodiments of the present disclosure;

FIG. 17 is a schematic diagram of forming a source and drain layer and a second wiring segment according to some embodiments of the present disclosure;

FIG. 18 is a schematic diagram of plasma treatment according to some embodiments of the present disclosure;

FIG. 19 is a schematic diagram of forming a semiconductor modification layer according to some embodiments of the present disclosure; and

FIG. 20 is a schematic structural diagram of a display device according to some embodiments of the present disclosure.

### DETAILED DESCRIPTION

For clearer descriptions of the objectives, technical solutions, and advantages of the present disclosure, the embodiments of the present disclosure are described in detail hereinafter with reference to the accompanying drawings.

Thin-film transistors (TFT), as a switch control element of a pixel circuit or an integrated element of a periphery driving circuit, are core elements of a display device, and affect a resolution, a response speed, and a color reality of the display device. A metal oxide semiconductor thin-film transistor has attracted much attention in recent years due to advantages, such as the high mobility, the great uniformity, the low processing temperature, the high transmittance in the visible light region, and the like.

Currently, a mobility of mass-produced metal oxide semiconductor thin-film transistors on the market is about 10 cm²/V·s, which requires to be further improved to meet requirements of the greater resolution and fresh rate, and the narrower frame. It is necessary to reduce the size of the thin-film transistor on the premise that the property of the thin-film transistor is not changed or greater, such that the resolution and the response speed of the display panel are improved, and the power consumption is reduced. For the metal oxide semiconductor thin-film transistor, an electrics property of the thin-film transistor is greatly affected by a quality of a film layer a semiconductor layer (an active layer) of the thin-film transistor, and thus the quality of the film layer of the semiconductor layer requires to be improved. Currently, for improvement of the quality of the film layer of the semiconductor layer, the semiconductor layer is baked at a high temperature (for example, a temperature greater than 350° C.) upon formation of the semiconductor layer.

However, as the processing temperature of the reaction chamber is great in manufacturing the thin-film transistor, a source and drain layer of the thin-film transistor is prone to damage, such that a yield of the display panel is poor.

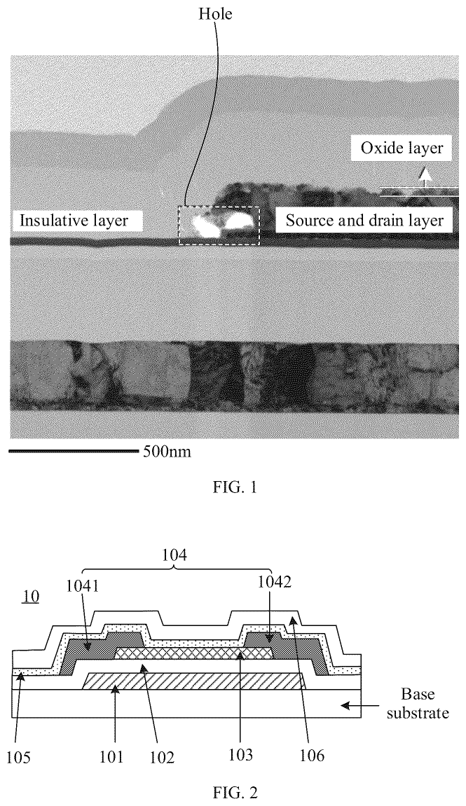

Referring to FIG. 1, a great hole is present in a source and drain layer of the thin-film transistor, and the processing temperature is great, such that a side, distal from a base substrate, of the source and drain layer is prone to forming an oxide layer, the source and drain layer is prone to corrosion by moisture and oxygen or short circuit, and the property of the thin-film transistor is poor.

FIG. 2 is a schematic structural diagram of a thin-film transistor according to some embodiments of the present disclosure. Referring to FIG. 2, the thin-film transistor 10 includes a gate 101, a first insulative layer 102, a semiconductor layer (also referred to as an active layer) 103, a source and drain layer 104, a semiconductor modification layer (or an active modification layer, AML) 105, and a second insulative layer 106 that are disposed on a base substrate and sequentially laminated in a direction away from the base substrate. The source and drain layer 104 includes a source(S) 1041 and a drain (D) 1042 that are spaced apart and both connected to the semiconductor layer 103, a portion of the semiconductor layer 103 is exposed from a gap between the source 1041 and the drain 1042, and the semiconductor modification layer 105 at least covers the portion of the semiconductor layer 103 exposed from the gap. The first insulative layer 102 is a gate insulative layer (GI), and the second insulative layer 106 is a passivation layer (PVX).

A concentration of hydrogen (H) in the semiconductor layer 103 is greater than a concentration threshold. That is, the content of the hydrogen in the semiconductor layer 103 is great. In addition, a temperature of a reaction chamber in manufacturing the thin-film transistor 10 is less than a temperature threshold. That is, the temperature of the reaction chamber is less than the temperature threshold in manufacturing the thin-film transistor 10, and the temperature of the reaction chamber is less.

A first temperature of the reaction chamber in forming the semiconductor modification layer 105 is less than a second temperature of the reaction chamber in forming the second insulative layer 106. That is, in manufacturing the thin-film transistor 10, the temperature of the reaction chamber in forming the semiconductor modification layer 105 is different from the temperature of the reaction chamber in forming the second insulative layer 106. The semiconductor modification layer 105 and the second insulative layer 106 are two different film layers.

In the embodiments of the present disclosure, as the temperature of the reaction chamber in manufacturing the thin-film transistor 10 is less than the temperature threshold, the backing process on the semiconductor layer 103 upon formation of the semiconductor layer 103 requires to be cancelled (as the temperature of the backing process is great). Thus, in manufacturing the thin-film transistor 10, the temperature of the reaction chamber is less, the formation of the film layers in the thin-film transistor 10 is controllable, such that the damage on the source and drain layer 104 formed upon manufacturing of the semiconductor layer 103 is avoided, and the yield of the display panel is ensured.

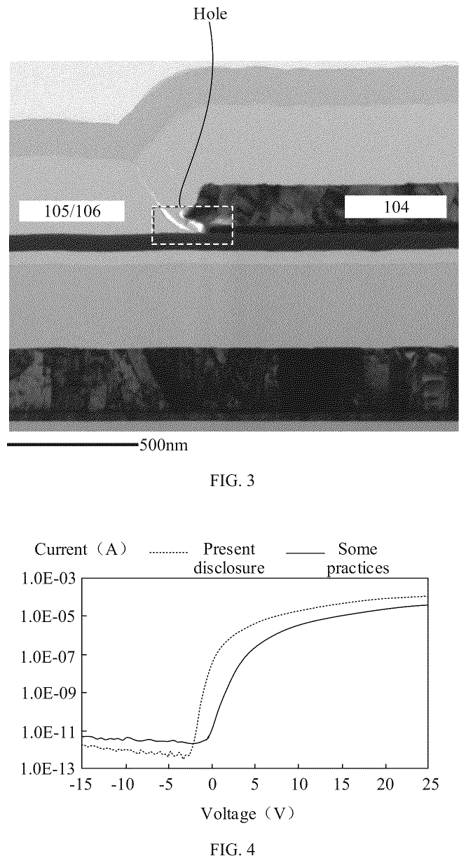

Illustratively, referring to FIG. 3, in the embodiments of the present disclosure, the hole in the source and drain layer 104 is reduced by adding the semiconductor modification layer 105 and cancelling the backing process on the semiconductor layer 103. In addition, the oxide layer is not formed on the side, distal from the base substrate, of the source and drain layer 104, such that the corrosion on the source and drain layer 104 by the introduced moisture and oxygen is avoided.

In addition, as the formation of the film layers in the thin-film transistor 10 is controllable, the content of the hydrogen in the semiconductor layer 103 is accurately controlled. Thus, the concentration of the hydrogen in the semiconductor layer 103 is controlled to be greater than the concentration threshold. The content of the hydrogen in the semiconductor layer 103 is great, and thus the hydrogen fills oxygen vacancies in the semiconductor layer 103 or replaces oxygen to form bonds with metal elements in the semiconductor layer 103. Thus, the addition of the hydrogen reduces the oxygen vacancies in the semiconductor layer 103. Generally, the quality of the film layer of the semiconductor layer 103 is improved in the case that the oxygen vacancies in the semiconductor layer 103 are less, such that the property of the thin-film transistor 10 is ensured.

In addition, the introduction of the hydrogen reduces the oxygen vacancies in the semiconductor layer 103. In conjunction with FIG. 4, compared with some practices, a sub-threshold swing of the thin-film transistor 10 in the embodiments of the present disclosure is less, and the property of the thin-film transistor 10 is great. The sub-threshold swing is a property index for measuring a transition rate between the on and off states of the thin-film transistor, and represents a change amount of a gate voltage required for a ten-times change of the current between the source and the drain. That is, the less the sub-threshold swing, the greater the property of the thin-film transistor.

In FIG. 4, the sub-threshold swing is determined by comparing slopes of current-voltage curves of the thin-film transistors (the voltage is the horizontal coordinate, and the current is the vertical coordinate). The greater the slope, the less the sub-threshold swing. The less the slope, the greater the sub-threshold swing. In FIG. 4, the slope of the current-voltage curve of the thin-film transistor in the embodiments of the present disclosure is greater than the slope of the current-voltage curve of the thin-film transistor in some practices, and thus the sub-threshold swing of the thin-film transistor in the embodiments of the present disclosure is less. For example, the sub-threshold swing of the thin-film transistor in some practices is 0.8 V/dec (the change amount of the gate voltage/the ten-times change of the current between the source and the drain), and the sub-threshold swing of the thin-film transistor in the embodiments of the present disclosure is 0.4 V/dec. In FIG. 4, the vertical coordinate represents the current with a unit of ampere (A), 1.0E-13 represents the negative 13^{th} power of 1.0 multiplied by 10, that is, 1.0×10\hat{ }−13, and the other are similar, which are not repeated.

In the embodiments of the present disclosure, the hydrogen is a shallow donor of the semiconductor layer 103, the stability of the hydrogen is less, and the hydrogen may transform to free carriers under a control of a less voltage, such that a concentration of the carriers of the semiconductor layer 103 is increased, and a contact resistance between the source 1041 and the drain 1042 and the semiconductor layer 103 of the thin-film transistor 10 is reduced. For example, it is found from tests that the contact resistance between the source 1041 and the drain 1042 and the semiconductor layer 103 of the thin-film transistor in some practices is 60 KΩ, and the contact resistance between the source 1041 and the drain 1042 and the semiconductor layer 103 of the thin-film transistor in the embodiments of the present disclosure is 6.6 KΩ.

In some embodiments, a transmission line model (TLM) is used to test the contact resistance between the source 1041 and the drain 1042 and the semiconductor layer 103 of the thin-film transistor, and the method includes the following processes.
1 A plurality of thin-film transistors are acquired. Widths of the channels of the plurality of thin-film transistors are equal, and lengths of the channels of the plurality of thin-film transistors are not equal.
2 Current-voltage curves of the plurality of thin-film transistors are acquired by tests. A gate and source voltage (a scan voltage) Vgs of the thin-film transistor ranges from −15 V to 25 V, and a source and drain voltage Vds of the thin-film transistor is 0.1 V.
3 For each thin-film transistor, currents at scan voltages of 5 V, 10 V, 15 V, and 20V are acquired based on the current-voltage curves, and a total resistance Rtotal of each thin-film transistor is calculated.

The total resistance Rtotal is equal to a voltage divided by a current. In addition, the total resistance Rtotal meets:

$$Rtotal = 2 Rc + Rchannel = 2 Rc + ( L - Δ L ) R 0. \qquad formula ( 1 )$$

In the above formula (1), Rc represents the contact resistance, Rchannel represents the resistance of the semiconductor, R0 represents the resistance of the semiconductor with a unit length, L represents the length of the channel of the thin-film transistor in theory, ΔL represents a difference between the length of the channel of the thin-film transistor in theory and in practice, and L−ΔL represents a valid length of the channel of the thin-film transistor.

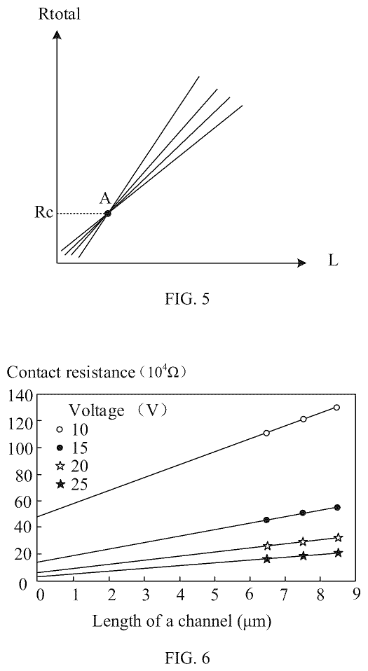

4 Four curves of the total resistance Rtotal and the valid length of the channel L−ΔL are acquired at four different scan voltages. Referring to FIG. 5, the four curves are linear and meet y=ax+b. y represents the total resistance Rtotal, and x represents the valid length of the channel L−ΔL. As the contact resistance 2Rc is not changed, a value of y corresponding to an intersection point A of the four curves is the contact resistance 2Rc.

In the embodiments of the present disclosure, referring to FIG. 6 and FIG. 7, comparing with the thin-film transistor in the embodiments of the present disclosure and the thin-film transistor in some practices, the contact resistance (a value of the vertical coordinate of the curve) of the thin-film transistor 10 in the embodiments of the present disclosure is less in the case of the same gate voltage Vg (the gate voltages of the four curves are different, for the curve with the same gate voltage in FIG. 6 and FIG. 7) and the same length L of the channel (the value of the horizontal coordinate of the curve).

In the embodiments of the present disclosure, compared with the thin-film transistor in some practices, the mobility of the thin-film transistor in the embodiments of the present disclosure is great. For example, it is found from tests that the mobility of the thin-film transistor in some practices is merely 18.4 cm²/V·s, and the mobility of the thin-film transistor 10 in the embodiments of the present disclosure is 32.9 cm²/V·s.

In some practices, the current Ids between the source 1041 and the drain 1042 of the thin-film transistor 10 meets:

$$Ids = μ * cox * \frac{W}{L} ( V gs - V th - \frac{1}{2} V ds ) . \qquad formula ( 2 )$$

In the above formula (2), μ represents the mobility of the thin-film transistor, Cox represents a capacitance of the thin-film transistor in a unit area, W represents the width of the channel of the thin-film transistor, L represents the length of the channel of the thin-film transistor, Vgs represents the gate and source voltage of the thin-film transistor, Vth represents the threshold voltage of the thin-film transistor, and the Vds represents the source and drain voltage of the thin-film transistor.

Thus, a transconductance gm formula of the thin-film transistor derived based on the above formula (2) is the following formula (3):

$$gm = \frac{dIds}{d V gs} = μ * ( Cox * \frac{W}{L} * V ds ) . \qquad formula ( 3 )$$

The transconductance gm represents a ratio of a change amount of the current to a change amount of the voltage.

A mobility μ formula (4) of the thin-film transistor is derived based on the above formula (3), and the mobility of the thin-film transistor is acquired based on the following formula (4):

$$μ = \frac{dIds}{d V gs} / ( Cox * \frac{W}{L} * V ds ) . \qquad formula ( 4 )$$

Furthermore, compared with the thin-film transistor in some practices, the on state current of the thin-film transistor in the embodiments of the present disclosure is great. For example, it is found from tests that the on state current of the thin-film transistor in some practices is merely 9.9 μA, and the on state current of the thin-film transistor in the embodiments of the present disclosure is 36.6 μA. The on state current of the thin-film transistor is a ratio of the current of the drain 1042 to a width/length (W/L) of the channel in the case that the gate and source voltage Vgs is 15 V.

In summary, a thin-film transistor is provided in the embodiments of the present disclosure. As the concentration of the hydrogen in the semiconductor layer in the thin-film transistor is greater than the concentration threshold, the hydrogen fills the oxygen vacancies in the semiconductor layer, such that the oxygen vacancies in the semiconductor layer are reduced. Thus, the quality of the film layer of the semiconductor layer is ensured, and the property of the thin-film transistor is ensured. In addition, as the temperature of the reaction chamber in manufacturing the thin-film transistor is less than the temperature threshold, the formation of the film layers in the thin-film transistor is controllable, such that the damage on the source and drain layer formed is avoided, and the yield of the display panel is ensured.

In addition, compared with the thin-film transistor in some practices, the sub-threshold swing of the thin-film transistor in the embodiments of the present disclosure is less, the contact resistance is less, the mobility and the on state current are great, and the property of the thin-film transistor is great.

In the embodiments of the present disclosure, in a face, proximal to the base substrate 20, of the semiconductor modification layer 105, a distance between a portion most proximal to the base substrate 20 and a portion most distal from the base substrate 20 in a direction perpendicular to a bearing face of the base substrate 20 is greater than or equal to 0 nm and less than or equal to 15 nm. That is, a distance between an upmost point and a lowest point of the face, proximal to the base substrate 20, of the semiconductor modification layer 105 in the direction perpendicular to the bearing face of the base substrate is less, a roughness of the face, proximal to the base substrate 20, of the semiconductor modification layer 105 is less, and the flatness is great.

In the embodiments of the present disclosure, the hydrogen in the semiconductor layer 103 is introduced in manufacturing the semiconductor modification layer 105 and the second insulative layer 106. Both a film forming gas of the semiconductor modification layer 105 and a film forming gas of the second insulative layer 106 include a gas containing hydrogen. That is, the hydrogen in the semiconductor layer 103 is doped in manufacturing the semiconductor modification layer 105 and the second insulative layer 106. Thus, it is not necessary to change the device and structure for manufacturing the thin-film transistor, and the cost is saved.

In some embodiments, the film forming gas of the semiconductor modification layer 105 includes silicon tetrahydride (SiH₄), and the film forming gas of the second insulative layer 106 includes silicon tetrahydride and ammonia (NH₃).

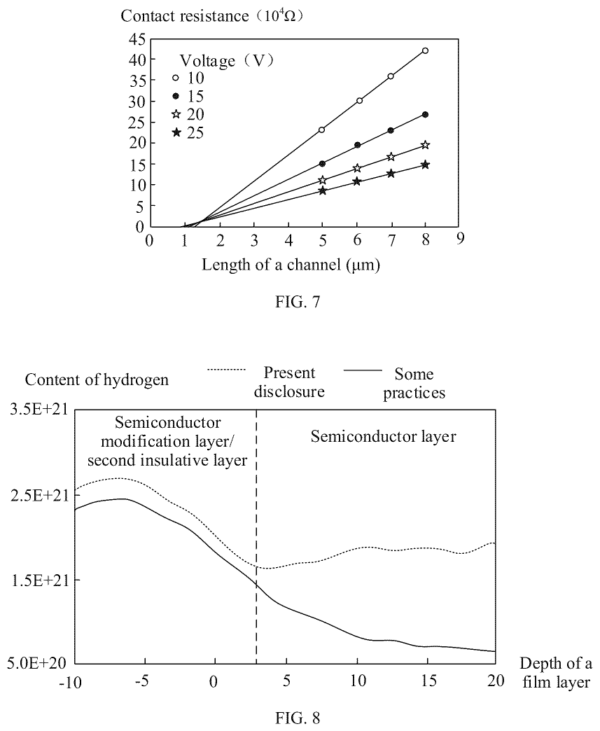

FIG. 8 is a schematic diagram of a curve of a content of hydrogen of a semiconductor layer 103, a content of hydrogen of a semiconductor modification layer 105, and a content of hydrogen of a second insulative layer 106 according to some embodiments of the present disclosure. In FIG. 8, the horizontal axis represents a depth of a film layer, and a position of 0 on the horizontal axis represents an interface of the semiconductor modification layer/second insulative layer. The vertical axis represents the content of the hydrogen, which is represented by a number of hydrogen atoms in per cubic centimeter (that is, the concentration of the hydrogen) with a unit of atom/cm³. 5.0E+20 represents the 20^{th} power of 5 multiplied by 10, that is, 5×10\hat{ }20, and the other are similar, which are not repeated.

In some practices, the number of the hydrogen atoms in per cubic centimeter of the semiconductor layer is about 5×10\hat{ }20. In the embodiments of the present disclosure, the number of the hydrogen atoms in per cubic centimeter of the semiconductor layer 103 is greater than 16×10\hat{ }20 and less than 26×10\hat{ }20. That is, the concentration of the hydrogen in the semiconductor layer in some practices is about 5×10\hat{ }20 atom/cm³, and the concentration of the hydrogen in the semiconductor layer 103 in the embodiments of the present disclosure is greater than 16×10\hat{ }20 atom/cm³ and less than 26×10\hat{ }20 atom/cm³. For example, the concentration of the hydrogen in the semiconductor layer 103 is 18×10\hat{ }20 atom/cm³.

It can be seen referring to FIG. 8 that compared with the case that the semiconductor modification layer 105 is not provided, and the semiconductor layer 103 is backed (in some practices), in the embodiments of the present disclosure, the semiconductor modification layer 105 is added prior to formation of the second insulative layer 106, and the backing process on the semiconductor layer 103 is cancelled, such that the content of the hydrogen in the semiconductor layer 103 is increased. Thus, the quality of the film layer of the semiconductor layer 103 is improved, and the property of the thin-film transistor 10 is ensured.

Whether the doped hydrogen in the semiconductor layer 103 is from the semiconductor modification layer 105 or the second insulative layer 106 is determined by determining the contents of the hydrogen in the semiconductor layers 103 in the two target transistors (not the thin-film transistor in the embodiments of the present disclosure). The first target transistor includes the semiconductor modification layer 105, but not includes the second insulative layer 106. The second target transistor includes the second insulative layer 106, but not includes the semiconductor modification layer 105. The number of the hydrogen atoms in per cubic centimeter of the first target transistor at an interface of the semiconductor modification layer 105 and the semiconductor layer 103 is 16×10\hat{ }20. That is, the concentration of the hydrogen in the first target transistor at the interface of the semiconductor modification layer 105 and the semiconductor layer 103 is 16×10\hat{ }20 atom/cm³. The number of the hydrogen atoms in per cubic centimeter of the second target transistor at an interface of the second insulative layer 106 and the semiconductor layer 103 is 13×10\hat{ }20. That is, the concentration of the hydrogen in the second target transistor at the interface of the second insulative layer 106 and the semiconductor layer 103 is 13×10\hat{ }20 atom/cm³. Thus, it can be seen that the concentration of the hydrogen in the first target transistor disposed with the semiconductor modification layer 105 and not disposed with the second insulative layer 106 is greater than the concentration of the hydrogen in the second target transistor not disposed with the semiconductor modification layer 105 and disposed with the second insulative layer 106.

Thus, it can be seen that the content of the hydrogen in the semiconductor layer 103 from the hydrogen in the silicon tetrahydride introduced to the reaction chamber in forming the semiconductor modification layer 105 is greater than the content of the hydrogen in the semiconductor layer 103 from the hydrogen in the silicon tetrahydride and the ammonia introduced to the reaction chamber in forming the second insulative layer 106. That is, a large amount of the hydrogen doped in the semiconductor layer 103 is from the hydrogen in the silicon tetrahydride introduced in forming the semiconductor modification layer 105, and a less amount of the hydrogen doped in the semiconductor layer 103 is from the the hydrogen in the silicon tetrahydride and the ammonia introduced in forming the second insulative layer 106.

Referring to FIG. 8 and compared with some practices, the contents of the hydrogen in the semiconductor modification layer 105 and the second insulative layer 106 are appropriately added in the embodiments of the present disclosure. A difference between the content of the hydrogen in the semiconductor modification layer 105 and the content of the hydrogen in the second insulative layer 106 is less. Illustratively, the number of the hydrogen atoms in per cubic centimeter of the semiconductor modification layer 105 is greater than 13×10\hat{ }20 and less than 23×10\hat{ }20. That is, the concentration of the hydrogen in the semiconductor modification layer 105 is greater than 13×10\hat{ }20 atom/cm³ and less than 23×10\hat{ }20 atom/cm³. The number of the hydrogen atoms in per cubic centimeter of the second insulative layer 106 is greater than 16×10\hat{ }20 and less than 26×10\hat{ }20. That is, the concentration of the hydrogen in the second insulative layer 106 is greater than 16×10\hat{ }20 atom/cm³ and less than 26×10\hat{ }20 atom/cm³.

In some embodiments, the temperature threshold is less than or equal to 350° C. The first temperature of the reaction chamber in forming the semiconductor modification layer 105 ranges from 130° C. to 200° C., for example, 160° C. The second temperature of the reaction chamber in forming the second insulative layer 106 ranges from 220° C. to 340° C., for example, 230° C.

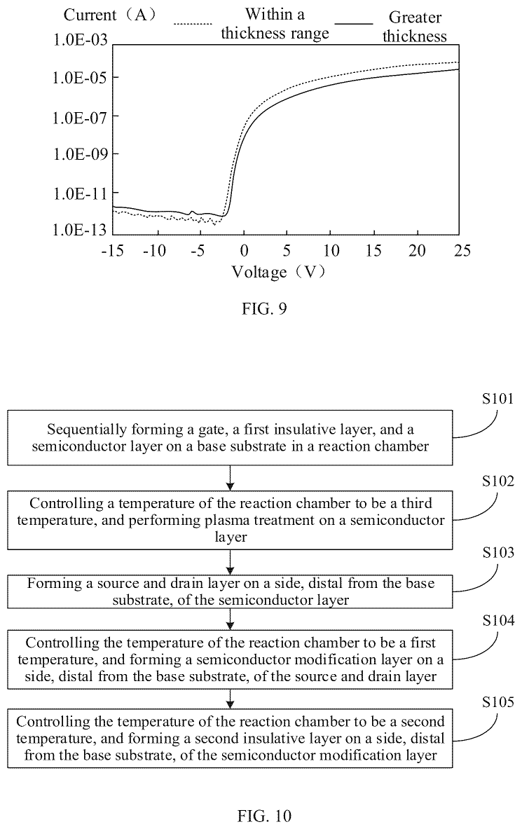

In the embodiments of the present disclosure, the less thickness of the semiconductor modification layer 105 may cause the poor uniformity of the film layer of the semiconductor modification layer 105, and the morphology of the film layer may be the morphology of the source and drain layer shown in FIG. 1. Referring to FIG. 9, the greater thickness of the semiconductor modification layer 105 may cause that the unstable property of the semiconductor modification layer 105, more defects are present in the film layer, and the property of the thin-film transistor is affected. For example, it can be seen from FIG. 9 that the greater thickness may cause the increased sub-threshold swing of the thin-film transistor and the reduced mobility and normalized current of the thin-film transistor. In FIG. 9, the vertical axis represents the current with a unit of A, 1.0E-13 represents the negative 13^{th} power of 1.0 multiplied by 10, that is, 1.0×10\hat{ }−13, and the other are similar, which are not repeated.

Thus, in some embodiments, the thickness of the semiconductor modification layer 105 ranges from 20 nm to 200 nm. For example, the thickness of the semiconductor modification layer 105 ranges from 20 nm to 50 nm. That is, the thickness of the semiconductor modification layer 105 is not great and not less, such that the quality of the film layer of the semiconductor modification layer 105 is ensured.

The thickness of the second insulative layer 106 ranges from 100 nm to 350 nm.

In some embodiments, a ratio of the thickness of the semiconductor modification layer 105 to the thickness of the second insulative layer 106 ranges from 1/25 to ⅓. For example, the ratio of the thickness of the semiconductor modification layer 105 to the thickness of the second insulative layer 106 ranges from 1/15 to ¼.

In some embodiments, a material of the semiconductor layer 103 includes an oxide, for example, an indium gallium zinc oxide (IGZO). In some embodiments, the material of the semiconductor layer 103 includes other materials, for example, a low temperature poly-silicon (LTPS), an indium gallium zinc tin oxide (In—Ga—Zn—Sn—O, IGZTO), an indium gallium oxide (In—Ga—O), and the like.

A material of the semiconductor modification layer 105 includes a silicon oxide (SiO₂). A material of the second insulative layer 106 includes a silicon oxide, or the material of the second insulative layer 06 includes a silicon oxide and a silicon nitride (SiNx). The material of the semiconductor modification layer 105 and the material of the second insulative layer 106 are the same or different, which is not limited in the embodiments of the present disclosure.

It should be noted that the semiconductor modification layer 105 is manufactured by an atomic layer deposition (ALD) process, or a chemical vapor deposition (CVD) process. Considering the actual process difficulty, the semiconductor modification layer 105 is generally manufactured by the CVD process. In some embodiments, the second insulative layer 106 is also manufactured by the CVD process.

In summary, a thin-film transistor is provided in the embodiments of the present disclosure. As the concentration of the hydrogen in the semiconductor layer in the thin-film transistor is greater than the concentration threshold, the hydrogen fills the oxygen vacancies in the semiconductor layer, such that the oxygen vacancies in the semiconductor layer are reduced. Thus, the quality of the film layer of the semiconductor layer is ensured, and the property of the thin-film transistor is ensured. In addition, as the temperature of the reaction chamber in manufacturing the thin-film transistor is less than the temperature threshold, the formation of the film layers in the thin-film transistor is controllable, such that the damage on the source and drain layer formed is avoided, and the yield of the display panel is ensured.

FIG. 10 is a flowchart of a method for manufacturing a thin-film transistor according to some embodiments of the present disclosure. The method is applicable to manufacturing the thin-film transistor in the above embodiments. Referring to FIG. 10, the method includes the following processes.

In S101, a gate, a first insulative layer, and a semiconductor layer are sequentially formed on a base substrate in a reaction chamber.

In the embodiments of the present disclosure, the film layers in the thin-film transistor are manufactured in the reaction chamber. In the manufacturing process, the corresponding gas is introduced to the reaction chamber to deposit the corresponding film layer. For example, in manufacturing the thin-film transistor, the base substrate is provided in the reaction chamber, and the gate, the first insulative layer, and the semiconductor layer are sequentially formed on the base substrate.

In S102, a temperature of the reaction chamber is controlled to be a third temperature, and plasma treatment is performed on a semiconductor layer.

In the embodiments of the present disclosure, the temperature of the reaction chamber is controlled to be the third temperature, and the plasma treatment is performed on the semiconductor layer 103 by introducing a treating gas to the reaction chamber. The third temperature is less than a temperature threshold. The third temperature ranges from 130° C. to 200° C., for example, 160° C. The treating gas is the nitrous oxide (N₂O), or a mixed gas of nitrogen (N₂) and the nitrous oxide.

That is, the temperature of the reaction chamber in performing the plasma treatment on the semiconductor layer is less, such that a subsequent vacuum annealing effect is reduced, the damage on the subsequently formed source and drain layer is avoided, and the stability of the thin-film transistor is ensured. In addition, as the temperature of the reaction chamber is less, the manufacturing the film layer is controllable, the concentration of the hydrogen in the semiconductor layer 103 is easily adjusted, and the quality of the film layer of the semiconductor layer 103 is improved.

In S103, a source and drain layer is formed on a side, distal from the base substrate, of the semiconductor layer.

The source and drain layer 104 includes a source 1041 and a drain 1042 that are spaced apart and both connected to the semiconductor layer 103, and a portion of the semiconductor layer 103 is exposed from a gap between the source 1041 and the drain 1042.

In S104, the temperature of the reaction chamber is controlled to be a first temperature, and a semiconductor modification layer is formed on a side, distal from the base substrate, of the source and drain layer.

The process of forming the semiconductor modification layer 105 includes: introducing silicon tetrahydride to the reaction chamber, and forming the semiconductor modification layer 105 on the side, distal from the base substrate, of the source and drain layer 104 by a chemical vapor deposition process. The semiconductor modification layer 105 at least covers the portion of the semiconductor layer 103 exposed from the gap.

In forming the semiconductor modification layer 105, the first temperature of the reaction chamber ranges from 130° C. to 200° C., for example, 160° C. The thickness of the semiconductor modification layer 105 ranges from 20 nm to 200 nm, for example, ranges from 20 nm to 50 nm. The material of the semiconductor modification layer 105 includes a silicon oxide.

It should be noted that in forming the semiconductor modification layer 105, the hydrogen in the silicon tetrahydride introduced to the reaction chamber is diffused and doped to the portion of the semiconductor layer 103 exposed from the source and drain layer 104, such that the content of the hydrogen in the semiconductor layer 103 is increased.

In S105, the temperature of the reaction chamber is controlled to be a second temperature, and a second insulative layer is formed on a side, distal from the base substrate, of the semiconductor modification layer.

The process of forming the second insulative layer 106 includes: introducing the silicon tetrahydride and ammonia to the reaction chamber, and forming the second insulative layer 106 on the side, distal from the base substrate, of the semiconductor modification layer 105 by the chemical vapor deposition process.

The second temperature is greater than the first temperature. In forming the second insulative layer 106, the second temperature of the reaction chamber ranges from 220° C. to 340° C., for example, 240° C. The thickness of the second insulative layer 106 ranges from 100 nm to 350 nm. The material of the second insulative layer 106 includes a silicon oxide, or a silicon oxide and a silicon nitride.

It should be noted that in forming the second insulative layer 106, the hydrogen in the silicon tetrahydride and the ammonia introduced to the reaction chamber is diffused and doped to the portion of the semiconductor layer 103 exposed from the gap between the source and the drain of the source and drain layer 104, such that the content of the hydrogen in the semiconductor layer 103 is increased.

In the hydrogen in the semiconductor layer 103, a content of the hydrogen in the silicon tetrahydride introduced to the reaction chamber in forming the semiconductor modification layer 105 is greater than a content of the hydrogen in the silicon tetrahydride and the ammonia introduced to the reaction chamber in forming the second insulative layer 106.

In the embodiments of the present disclosure, as the temperature of the reaction chamber in manufacturing the thin-film transistor 10 is less than the temperature threshold, the backing process on the semiconductor layer 103 upon formation of the semiconductor layer 103 requires to be cancelled (as the temperature of the backing process is great). Thus, in manufacturing the thin-film transistor 10, the temperature of the reaction chamber is less, the formation of the film layers in the thin-film transistor 10 is controllable, such that the damage on the source and drain layer 104 formed upon manufacturing of the semiconductor layer 103 is avoided, and the yield of the display panel is ensured.

In addition, the concentration of the hydrogen in the semiconductor layer 103 in the acquired thin-film transistor 10 is greater than the concentration threshold. That is, the content of the hydrogen in the semiconductor layer 103 is great, and thus the hydrogen fills oxygen vacancies in the semiconductor layer 103 or replaces oxygen to form bonds with metal elements in the semiconductor layer 103. Thus, the addition of the hydrogen reduces the oxygen vacancies in the semiconductor layer 103. Generally, the quality of the film layer of the semiconductor layer 103 is improved in the case that the oxygen vacancies in the semiconductor layer 103 are less, such that the property of the thin-film transistor 10 is ensured.

In summary, a method for manufacturing a thin-film transistor is provided in the embodiments of the present disclosure. As the concentration of the hydrogen in the semiconductor layer in the thin-film transistor is greater than the concentration threshold, the hydrogen fills the oxygen vacancies in the semiconductor layer, such that the oxygen vacancies in the semiconductor layer are reduced. Thus, the quality of the film layer of the semiconductor layer is ensured, and the property of the thin-film transistor is ensured. In addition, as the temperature of the reaction chamber in manufacturing the thin-film transistor is less than the temperature threshold, the formation of the film layers in the thin-film transistor is controllable, such that the damage on the source and drain layer formed is avoided, and the yield of the display panel is ensured.

As the method for manufacturing the thin-film transistor achieves the same technical effects as the thin-film transistor in the above embodiments, the other technical effects of the method for manufacturing the thin-film transistor are not repeated herein for clarity.

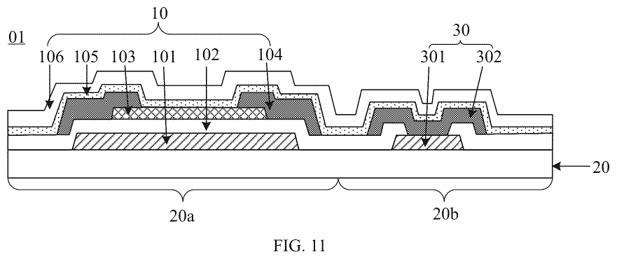

FIG. 11 is a schematic structural diagram of a display panel according to some embodiments of the present disclosure. Referring to FIG. 11, the display panel 01 includes a base substrate 20 and a plurality of thin-film transistors 10 on the base substrate 20.

Referring to FIG. 11, the base substrate 20 includes a display region 20a and a periphery region 20b surrounding the display region 20a. The plurality of thin-film transistors 10 in the display panel 01 are disposed at least in the display region 20a, and the thin-film transistors 10 in the display region 20a are a part of a pixel driving circuit of a pixel unit.

Referring to FIG. 11, the display panel further includes a signal wiring 30 in the periphery region 20b. The signal wiring 30 generally requires two layers of film layer connecting wirings. For example, the signal wiring 30 includes a first wiring segment 301 and a second wiring segment 302 that are disposed in different layers. The display panel 01 further includes a target insulative layer between the first wiring segment 301 and the second wiring segment 302, and the first wiring segment 301 is electrically connected to the second wiring segment 302 by a via in the target insulative layer.

In some embodiments, the first wiring segment 301 and the gate 101 in the thin-film transistor 10 are made of the same material by one patterning process, and the second wiring segment 302 and the source and drain layer 104 are made of the same material by one patterning process. The target insulative layer is an insulative layer between the gate 101 and the source and drain layer 104, for example, the first insulative layer 102.

As the display panel 01 achieves the same technical effects as the thin-film transistor 10 in the above embodiments, the other technical effects of the display panel 01 are not repeated herein for clarity.

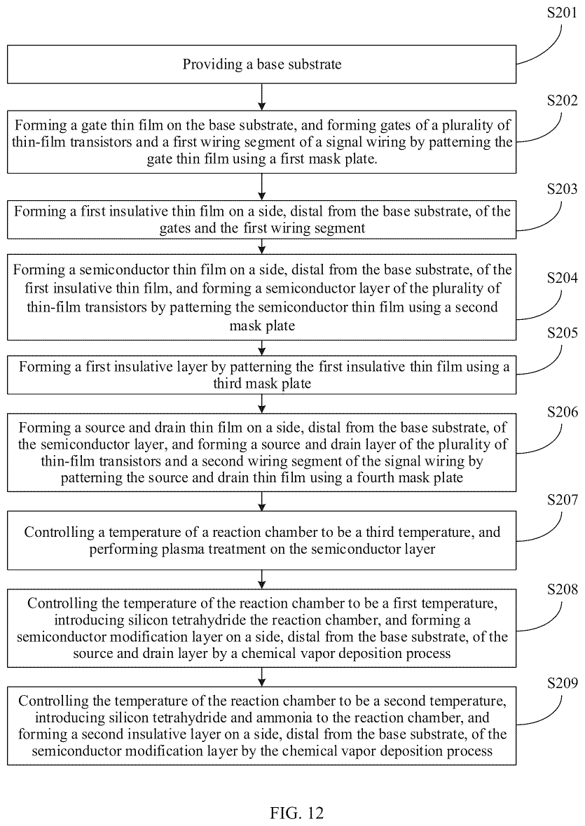

FIG. 12 is a flowchart of a method for manufacturing a display panel according to some embodiments of the present disclosure. The method is applicable to manufacturing the display panel in the above embodiments. Referring to FIG. 12, the method includes the following processes.

In S201, a base substrate is provided.

In the embodiments of the present disclosure, in manufacturing the display panel, the base substrate is first acquired. The base substrate is a glass substrate or a flex substrate.

In S202, a gate thin film is formed on the base substrate, and gates of a plurality of thin-film transistors and a first wiring segment of a signal wiring are formed by patterning the gate thin film using a first mask plate.

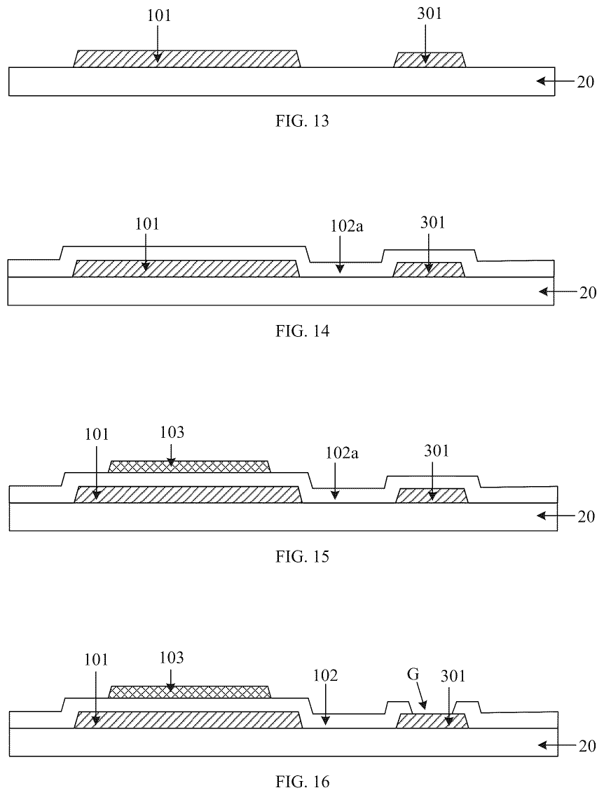

In the embodiments of the present disclosure, the gate thin film is formed on the base substrate, and is patterned (may be a patterning process) using the first mask plate. Referring to FIG. 13, the gates 101 of the plurality of thin-film transistors 10 and the first wiring segment 301 of the signal wiring 30 are formed upon patterning.

The patterning process includes photoresist coating, exposing, developing, etching, and photoresist remocing.

In some embodiments, a material of the gate thin film is metal.

In S203, a first insulative thin film is formed on a side, distal from the base substrate, of the gates and the first wiring segment.

Referring to FIG. 14, the first insulative thin film 102a is configured to protect the gates 101 and the first wiring segment 301, and insulate the subsequently formed film layers from the gates 101 and the first wiring segment 301.

In S204, a semiconductor thin film is formed on a side, distal from the base substrate, of the first insulative thin film, and a semiconductor layer of the plurality of thin-film transistors is formed by patterning the semiconductor thin film using a second mask plate.

In the embodiments of the present disclosure, the semiconductor thin film is formed on the side, distal from the base substrate 20, of the first insulative thin film 102a, and is patterned using the second mask plate. Referring to FIG. 15, the semiconductor layer 103 of the plurality of thin-film transistors 10 is formed upon patterning.

In S205, a first insulative layer is formed by patterning the first insulative thin film using a third mask plate.

In the embodiments of the present disclosure, referring to FIG. 16, the first insulative layer 102 is provided with a via (also referred to as a connecting via). The via G is disposed in the periphery region, and is configured to expose at least a part of the first wiring segment 301. The via is configured to cause the subsequently formed second wiring segment 302 to be in contact with the first wiring segment 301.

In S206, a source and drain thin film is formed on a side, distal from the base substrate, of the semiconductor layer, and a source and drain layer of the plurality of thin-film transistors and a second wiring segment of the signal wiring are formed by patterning the source and drain thin film using a fourth mask plate.

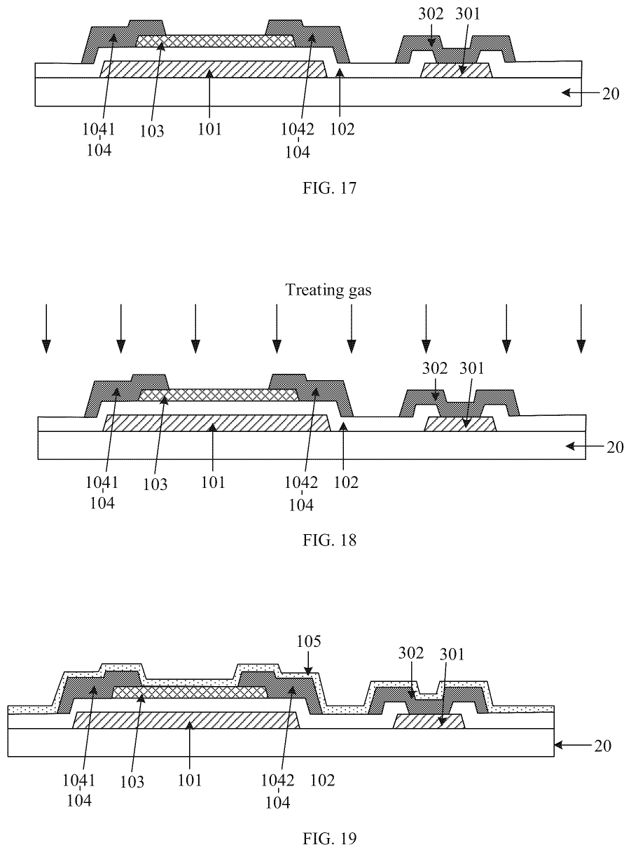

In the embodiments of the present disclosure, the source and drain thin film is formed on the side, distal from the base substrate, of the semiconductor layer 103, and is patterned using the fourth mask plate. Referring to FIG. 17, the source and drain layer 104 of the plurality of thin-film transistors 10 and the second wiring segment 302 of the signal wiring 30 are formed upon patterning.

The source and drain layer 104 includes a source 1041 and a drain 1042 that are spaced apart and both connected to the semiconductor layer 103, and a portion of the semiconductor layer 103 is exposed from a gap between the source 1041 and the drain 1042, such that the subsequently formed semiconductor modification layer 105 is in contact with the portion of the semiconductor layer 103 exposed from the gap. The second wiring segment 302 of the signal wiring is connected to the first wiring segment 301 of the signal wiring by the via in the first insulative layer 102, such that the connection and transmission of the signal are achieved.

In S207, a temperature of the reaction chamber is controlled to be a third temperature, and plasma treatment is performed on the semiconductor layer.

In the embodiments of the present disclosure, the display panel is manufactured in the reaction chamber. Upon formation of the source and drain layer 104 and the second wiring segment 302, referring to FIG. 18, the temperature of the reaction chamber is controlled to be the third temperature, and the plasma treatment is performed on the semiconductor layer 103 by introducing a treating gas to the reaction chamber. The third temperature is less than a temperature threshold. The third temperature ranges from 130° C. to 200° C., for example, 160° C. The treating gas is the nitrous oxide (N₂O), or a mixed gas of nitrogen (N₂) and the nitrous oxide.

In S208, the temperature of the reaction chamber is controlled to be a first temperature, silicon tetrahydride is introduced to the reaction chamber, and a semiconductor modification layer is formed on a side, distal from the base substrate, of the source and drain layer by a chemical vapor deposition process.

In the embodiments of the present disclosure, referring to FIG. 19, the semiconductor modification layer 105 covers the portion of the semiconductor layer 103 exposed from the gap. In forming the semiconductor modification layer 105, the first temperature of the reaction chamber ranges from 130° C. to 200° C., for example, 160° C. The thickness of the semiconductor modification layer 105 ranges from 20 nm to 200 nm, for example, from 20 nm to 50 nm. The material of the semiconductor modification layer 105 includes the silicon oxide.

It should be noted that in forming the semiconductor modification layer 105, the hydrogen in the silicon tetrahydride introduced to the reaction chamber is diffused and doped to the portion of the semiconductor layer 103 exposed from the source and drain layer 104, such that the content of the hydrogen in the semiconductor layer 103 is improved.

In S209, the temperature of the reaction chamber is controlled to be a second temperature, silicon tetrahydride and ammonia are introduced to the reaction chamber, and a second insulative layer is formed on a side, distal from the base substrate, of the semiconductor modification layer by the chemical vapor deposition process.

The second temperature is greater than the first temperature. In forming the second insulative layer 106, the second temperature of the reaction chamber ranges from 220° C. to 340° C., for example, 240° C. The thickness of the second insulative layer 106 ranges from 100 nm to 350 nm. The material of the second insulative layer 106 includes the silicon oxide, or the silicon oxide and the silicon nitride.

It should be noted that in forming the second insulative layer 106, the hydrogen in the silicon tetrahydride and the ammonia introduced to the reaction chamber is diffused and doped to the portion of the semiconductor layer 103 exposed from the gap between the source and the drain of the source and drain layer, such that the content of the hydrogen in the semiconductor layer 103 is improved. That is, in conjunction with S208 and S209, the hydrogen in the semiconductor layer 103 is from the hydrogen in the silicon tetrahydride introduced to the reaction chamber in forming the semiconductor modification layer 105 and the hydrogen in the silicon tetrahydride and the ammonia introduced to the reaction chamber in forming the second insulative layer 106.

The concentration of the hydrogen in the semiconductor layer 103 is greater than a concentration threshold. In addition, in the hydrogen in the semiconductor layer 103, a content of the hydrogen in the silicon tetrahydride introduced to the reaction chamber in forming the semiconductor modification layer 105 is greater than a content of the hydrogen in the silicon tetrahydride and the ammonia introduced to the reaction chamber in forming the second insulative layer 106.

In the embodiments of the present disclosure, the film layers formed in the reaction chamber are annealed upon formation of the second insulative layer 106. The temperature of the reaction chamber is controlled to be a fourth temperature in the annealing, and the fourth temperature ranges from 200° C. to 350° C.

In the embodiments of the present disclosure, as the temperature of the reaction chamber in manufacturing the display panel 01 is less than the temperature threshold, the backing process on the semiconductor layer 103 upon formation of the semiconductor layer 103 requires to be cancelled (as the temperature of the backing process is great). Thus, in manufacturing the display panel 01, the temperature of the reaction chamber is less, the formation of the film layers in the display panel 01 is controllable, such that the damage on the source and drain layer 104 formed upon manufacturing of the semiconductor layer 103 is avoided, and the yield of the display panel is ensured.

In addition, the concentration of the hydrogen in the semiconductor layer 103 in the acquired display panel is greater than the concentration threshold. That is, the content of the hydrogen in the semiconductor layer 103 is great, and thus the hydrogen fills oxygen vacancies in the semiconductor layer 103 or replaces oxygen to form bonds with metal elements in the semiconductor layer 103. Thus, the addition of the hydrogen reduces the oxygen vacancies in the semiconductor layer 103. Generally, the quality of the film layer of the semiconductor layer 103 is improved in the case that the oxygen vacancies in the semiconductor layer 103 are less, such that the property of the thin-film transistor 10 is ensured.

In summary, a method for manufacturing a display panel is provided in the embodiments of the present disclosure. As the concentration of the hydrogen in the semiconductor layer in the thin-film transistor in the acquired display panel is greater than the concentration threshold, the hydrogen fills the oxygen vacancies in the semiconductor layer, such that the oxygen vacancies in the semiconductor layer are reduced. Thus, the quality of the film layer of the semiconductor layer is ensured, and the property of the thin-film transistor is ensured. In addition, as the temperature of the reaction chamber in manufacturing the thin-film transistor is less than the temperature threshold, the formation of the film layers in the display panel is controllable, such that the damage on the source and drain layer formed is avoided, and the yield of the display panel is ensured.

As the method for manufacturing the display panel achieves the same technical effects as the thin-film transistor in the above embodiments, the other technical effects of the method for manufacturing the display panel are not repeated herein for clarity.

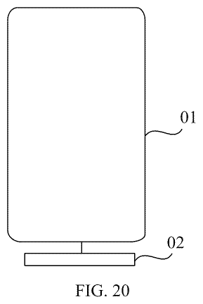

FIG. 20 is a schematic structural diagram of a display device according to some embodiments of the present disclosure. Referring to FIG. 20, the display device includes a power supply assembly 02 and the display panel 01 in the above embodiments. The power supply assembly 02 is configured to supply power to the display panel 01.

In some embodiments, the display device is a liquid crystal display (LCD) device, an organic light-emitting diode (OLED) display device, an electronic paper, a low temperature poly-silicon (LTPS) display device, a low temperature poly-silicon oxide (LTPO) display device, a mobile phone, a tablet personal computer, a television, a monitor, a laptop, a digital photo frame, a navigator and any other product or component with the display function.

As the display device achieves the same technical effects as the thin-film transistor in the above embodiments, the other technical effects of the method for manufacturing the display panel are not repeated herein for clarity.

The terms in the embodiments of the present disclosure are used to explain the embodiments of the present disclosure, and are not intended to limit the present disclosure. Unless otherwise defined, technical or scientific terms used in the embodiments of the present disclosure shall have ordinary meaning understood by persons of ordinary skill in the art to which the disclosure belongs. The terms “first,” “second,” and the like used in the embodiments of the present disclosure are not intended to indicate any order, quantity or importance, but are merely used to distinguish the different components. The terms “one” or “an” and the like are not used to limit the number, and are only used to indicate at least one. The terms “comprise” or “include” and the like are used to indicate that the element or object preceding the terms “comprise” or “include” covers the element or object following the terms “comprise” or “include” and its equivalents, and shall not be understood as excluding other elements or objects. The terms “connect” or “contact” and the like are not intended to be limited to physical or mechanical connections, but may include electrical connections, either direct or indirect connection. The terms “on,” “under,” “left” and “right” are only used to indicate the relative positional relationship. When the absolute position of the described object changes, the relative positional relationship may change accordingly.

Described above are merely exemplary embodiments of the present disclosure, and are not intended to limit the present disclosure. Any modifications, equivalent substitutions, improvements, and the like within the spirit and principles of the disclosure are included in the scope of protection of the present disclosure.

1. A thin-film transistor, comprising: a gate, a first insulative layer, a semiconductor layer, a source and drain layer, a semiconductor modification layer, and a second insulative layer that are disposed on a base substrate and sequentially laminated in a direction away from the base substrate; wherein
the source and drain layer comprises a source and a drain that are spaced apart and both connected to the semiconductor layer, a portion of the semiconductor layer is exposed from a gap between the source and the drain, and the semiconductor modification layer at least covers the portion of the semiconductor layer exposed from the gap; and
a number of hydrogen atoms in per cubic centimeter of the semiconductor layer is greater than 16×10\hat{ }20 and less than 26×10\hat{ }20.

2. The thin-film transistor according to claim 1, wherein in a face, proximal to the base substrate, of the semiconductor modification layer, a distance between a portion most proximal to the base substrate and a portion most distal from the base substrate in a direction perpendicular to a bearing face of the base substrate is greater than or equal to 0 nm and less than or equal to 15 nm.

3.-4. (canceled)

5. The thin-film transistor according to claim 1, wherein a ratio of a thickness of the semiconductor modification layer to a thickness of the second insulative layer ranges from 1/25 to ⅓.

6. The thin-film transistor according to claim 5, wherein the thickness of the semiconductor modification layer ranges from 20 nm to 200 nm, and the thickness of the second insulative layer ranges from 100 nm to 350 nm.

7. (canceled)

8. The thin-film transistor according to claim 1, wherein
a material of the semiconductor layer comprises an oxide;
a material of the semiconductor modification layer comprises a silicon oxide; and
a material of the second insulative layer comprises a silicon oxide, or a silicon oxide and a silicon nitride.

9. A method for manufacturing a thin-film transistor, comprising:
sequentially forming a gate, a first insulative layer, a semiconductor layer, and a source and drain layer on a base substrate in a reaction chamber, wherein the source and drain layer comprises a source and a drain that are spaced apart and both connected to the semiconductor layer, and a portion of the semiconductor layer is exposed from a gap between the source and the drain;
controlling a temperature of the reaction chamber to be a first temperature, and forming a semiconductor modification layer on a side, distal from the base substrate, of the source and drain layer, wherein the semiconductor modification layer at least covers the portion of the semiconductor layer exposed from the gap; and
controlling the temperature of the reaction chamber to be a second temperature, and forming a second insulative layer on a side, distal from the base substrate, of the semiconductor modification layer, wherein the second temperature is greater than the first temperature, a concentration of hydrogen in the semiconductor layer is greater than a concentration threshold, and the first temperature, the second temperature, and a temperature of the reaction chamber in forming the gate, the first insulative layer, the semiconductor layer, and the source and drain layer are all less than a temperature threshold.

10. The manufacturing method according to claim 9, wherein
forming the semiconductor modification layer on the side, distal from the base substrate, of the source and drain layer comprises:
introducing silicon tetrahydride to the reaction chamber, and forming the semiconductor modification layer on the side, distal from the base substrate, of the source and drain layer by a chemical vapor deposition process;
forming the second insulative layer on the side, distal from the base substrate, of the semiconductor modification layer comprises:
introducing silicon tetrahydride and ammonia to the reaction chamber, and forming the second insulative layer on the side, distal from the base substrate, of the semiconductor modification layer by the chemical vapor deposition process;
wherein the hydrogen in the semiconductor layer is from hydrogen in the silicon tetrahydride introduced to the reaction chamber in forming the semiconductor modification layer and hydrogen in the silicon tetrahydride and the ammonia introduced to the reaction chamber in forming the second insulative layer.

11. The manufacturing method according to claim 9, wherein in the hydrogen in the semiconductor layer, a content of hydrogen in silicon tetrahydride introduced to the reaction chamber in forming the semiconductor modification layer is greater than a content of hydrogen in silicon tetrahydride and ammonia introduced to the reaction chamber in forming the second insulative layer.

12. The manufacturing method according to claim 9, wherein upon formation of the source and drain layer and prior to formation of the semiconductor modification layer, the method further comprises:
controlling the temperature of the reaction chamber to be a third temperature, and performing plasma treatment on the semiconductor layer, wherein the third temperature is less than the temperature threshold.

13. The manufacturing method according to claim 9, wherein a number of hydrogen atoms in per cubic centimeter of the semiconductor layer is greater than 16×10\hat{ }20 and less than 26×10\hat{ }20.

14. The manufacturing method according to claim 9, wherein the temperature threshold is less than or equal to 250° C., the first temperature ranges from 130° C. to 200° C., and the second temperature ranges from 220° C. to 340° C.

15. A display panel, comprising: a base substrate and a plurality of thin-film transistors on the base substrate; wherein each of the plurality of thin-film transistors comprises: a gate, a first insulative layer, a semiconductor layer, a source and drain layer, a semiconductor modification layer, and a second insulative layer that are disposed on the base substrate and sequentially laminated in a direction away from the base substrate; wherein
the source and drain layer comprises a source and a drain that are spaced apart and both connected to the semiconductor layer, a portion of the semiconductor layer is exposed from a gap between the source and the drain, and the semiconductor modification layer at least covers the portion of the semiconductor layer exposed from the gap; and
a number of hydrogen atoms in per cubic centimeter of the semiconductor layer is greater than 16×10\hat{ }20 and less than 26×10\hat{ }20.

16. The display panel according to claim 15, wherein the base substrate comprises a display region and a periphery region surrounding the display region, the plurality of thin-film transistors are at least disposed in the display region, and the display panel further comprises: a signal wiring in the periphery region, wherein
the signal wiring comprises a first wiring segment and a second wiring segment that are disposed in different layers, the display panel further comprises a target insulative layer between the first wiring segment and the second wiring segment, and the first wiring segment is electrically connected to the second wiring segment by a via in the target insulative layer.

17. The display panel according to claim 16, wherein the first wiring segment and the gate are made of the same material by one patterning process, the second wiring segment and the source and drain layer are made of the same material by one patterning process, and the target insulative layer is the first insulative layer.

18. The display panel according to claim 15, wherein in a face, proximal to the base substrate, of the semiconductor modification layer, a distance between a portion most proximal to the base substrate and a portion most distal from the base substrate in a direction perpendicular to a bearing face of the base substrate is greater than or equal to 0 nm and less than or equal to 15 nm.

19. The display panel according to claim 15, wherein a ratio of a thickness of the semiconductor modification layer to a thickness of the second insulative layer ranges from 1/25 to ⅓.

20. The display panel according to claim 19, wherein the thickness of the semiconductor modification layer ranges from 20 nm to 200 nm, and the thickness of the second insulative layer ranges from 100 nm to 350 nm.

21. The display panel according to claim 15, wherein
a material of the semiconductor layer comprises an oxide;
a material of the semiconductor modification layer comprises a silicon oxide; and
a material of the second insulative layer comprises a silicon oxide, or a silicon oxide and a silicon nitride.
